(19) United States
(12) Patent Application Publication
(10) Pub. No.: US 2006/0263925 A1
(43) Pub. Date: Nov. 23, 2006

(54) Ethernet-powered particle counting system

(76) Inventor: David L. Chandler, Highland, CA (US)

Correspondence Address: JANSSON, SHUPE, MUNGER & ANTARAMIAN, LTD, 245 MAIN STREET, RACINE, WI, 53403, US

(21) Appl. No.: 11/125,453

(22) Filed: May 10, 2005

(51) Int. Cl. H01L 21/00

(52) U.S. Cl. 438/61

(57) ABSTRACT

A system includes a particle counter having a data output, an Ethernet cable adapted for connecting the data output of the particle counter to a monitoring station, and a power over Ethernet (POE) type power supply structured for providing power to the particle counter via the Ethernet cable. Apparatus includes a particle counter having an air movement device powered solely by a POE supply. Apparatus may include a particle counter having an air mover, power management subsystem, and Ethernet data output, the power management subsystem for monitoring power consumption of the air mover and maintaining the power consumption below a predetermined amount, and an electrical supply for powering the particle counter via an Ethernet medium. A method includes powering a particle counter over Ethernet medium via a POE power supply, detecting microscopic particles, and producing digital data based on the detecting, and transmitting the data over the Ethernet medium.

### FIELD OF THE INVENTION

The invention relates to particle sensing equipment and methods and, more particularly, to particle sensing systems adapted for network operation independent of wiring constraints such as those of an AC line input.

### BACKGROUND OF THE INVENTION

Particle sensors are used in a variety of applications, including liquid and aerosol particle counting and sizing operations. Such systems typically utilize a light source such as an infrared or HeNe laser for illuminating a sample space of a liquid or aerosol flow. The laser light is scattered by the particles in the flow sample, and a photo detector type sensor is used for receiving and analyzing the scattered light, such as for determining particle counts and/or sizes. Extinction type sensors may also be used for detecting shadows rather than scattered light. Such sensors may include collection optics, a photo detector, circuitry for converting detected scattered light or shadows to electrical signals, a circuit for discriminating electrical signals caused by given particles at a particle size of interest, and a circuit for counting the number of crossings of a particle size threshold, by the detection signals, over a predetermined period of time. By controlling the flow rate, a particle detection event can be expressed, for example, in terms of a count per unit volume.

Particle counters that detect microscopic particles in air and liquid may be used to monitor the relative degree of cleanliness of environments and process fluids, where contamination of a product being manufactured can render that product unsuitable for its intended purpose. For example, pharmaceutical manufacturers require environments that, in addition to having a high degree of cleanliness, are sterile. A goal of a sterile environment is the elimination of any viable organisms that could come in contact with a product being packaged or manufactured. Environments where pharmaceuticals are formulated and packaged are monitored in order to assure compliance with cleanliness standards established by government agencies.

Semiconductor manufacturers also monitor the cleanliness of their process fluids, gases, and environment in order to eliminate sources of contamination and to thereby increase yield. Other industries, for example those manufacturers of automotive products, portable equipment, micromachined structures, and optical assemblies, also monitor their environments to detect and control contamination that might affect product performance and quality levels.

Particle counters that operate on principles of light scattering may typically include apparatus for moving air through the sensor. Various types of air movers are commonly available for obtaining a particular flow rate, but efficiencies and power requirements of such air movers vary significantly.

A particle counter is typically adapted to transfer data to a computer for purposes including the correlation of particle count information with other activities in the environment or, for example, with a particular manufacturing process. One typical data transfer application includes an RS-232 or RS-485 connection between the particle counter and a host computer. With such a port, the particle counter can transfer data to the computer for storage, analysis, and particle detection reports. When a particle counter has a network port, data may also be transferred from such particle counter to the computer via a computer network. Such a particle counter must be connected to an electric supply source such as an AC line voltage. A disadvantage of some conventional particle counters concerns their use of an AC line voltage through what is typically a standard AC outlet, although some conventional particle counters have also considered a use of battery power. Such a battery system also has the disadvantage that it must eventually be connected to an external power supply for recharging the batteries.

Providing external power, such as an AC line voltage, to a particle counter causes particular problems in a sterile cleanroom, where all surfaces in the cleanroom, including those of the particle counter, must be disinfected by a process of cleaning that uses a disinfectant. AC power cords, of a type suitable for portable equipment, plug into sockets that cannot be sealed against the ingress of cleaning solutions. Such a cleaning solution will not reliably penetrate into the gaps between the cord and the socket. Some disinfectant solutions are corrosive to electrical contacts, which may cause reliability or safety concerns.

AC power is subject to outages. When power fails at a manufacturing plant, it is desirable for particle monitoring and counting to continue. For example, data collected by a particle counter during a power outage may be used to determine whether a given product that was exposed to the resident environment during the power outage has experienced any contamination. One solution to the power outage situation, an AC Uninterruptible Power Supply (UPS), is expensive to install and maintain for a separate instrumentation system.

### OBJECTS OF THE INVENTION

It is an object of the invention to provide an improved power source for particle counting instrumentation overcoming some of the problems and shortcomings of the prior art, including those referred to above.

Another object of the invention is to provide a particle counting system having a power management integrated with data transfer.

Another object of the invention is to provide a particle counting system adapted for an installation in a sterile cleanroom.

Still another object of the invention is to provide a particle counting system adapted for an installation that eliminates an AC power source conventionally used for powering the system.

Yet another object of the invention is to provide a particle counting system that communicates in a network without being limited by wiring or cabling constraints.

Another object of the invention is to provide a particle counting system that is adaptable to being implemented using a selected combination of power over Ethernet (POE) and wireless technology.

How these and other objects are accomplished will become apparent from the following descriptions and the drawings.

### SUMMARY OF THE INVENTION

According to an aspect of the invention, a system includes a particle counter having a data output, an Ethernet cable adapted for connecting the data output of the particle counter to a monitoring station, and a power over Ethernet (POE) type power supply structured for providing power to the particle counter via the Ethernet cable.

According to another aspect of the invention, apparatus includes a particle counter having an air movement device adapted for being powered solely by a power over Ethernet supply.

According to another aspect of the invention, a system includes a particle counter having an air mover, a power management subsystem, and an Ethernet data output, the power management subsystem structured for monitoring power consumption of the air mover and maintaining the power consumption below a predetermined amount, and an external electrical supply structured for powering the particle counter via an Ethernet medium using a power over Ethernet (POE) type power source.

According to another aspect of the invention, a method includes providing a particle counter having an Ethernet data output, and providing an external electrical supply for powering the particle counter via an Ethernet medium using a power over Ethernet (POE) type power source.

According to another aspect of the invention, a method includes powering a remote particle counter over an Ethernet medium via a power over Ethernet type power supply, detecting microscopic particles with the particle counter and producing digital data based on the detecting, and transmitting the data over the Ethernet medium.

According to another aspect of the invention, a system includes a power over Ethernet (POE) supply having a power supply adapted to transfer electrical power over an Ethernet cable that includes a data carrier, a wireless access point adapted for receiving a wireless data transmission and transferring the data from the transmission via the Ethernet cable, a wireless component structured for communicating with the wireless access point, and a particle counter that counts particles and outputs particle counting data.

As a result of implementing the present invention, an improved particle counting system may be implemented in a network independently of wiring constraints.

The foregoing summary does not limit the invention, which is instead defined by the attached claims.

### BRIEF DESCRIPTION OF THE DRAWING FIGURES

FIG. 1 is a highly schematic view of a particle counting system that implements power over Ethernet (POE), according to an exemplary embodiment of the invention.

FIGS. 2A-2C are basic configurations of conventional POE, and show different ways of implementing power sourcing equipment (PSE) for providing electrical to remote powered devices (PDs) via Ethernet twisted pair wiring.

FIGS. 3A and 3B provide a schematic for a pump control circuit of an exemplary embodiment of a POE particle counting system that uses pulse width modulation (PWM) for controlling operation of a blower portion of an air sampling section.

FIG. 4 is a simplified schematic showing a pump control circuit of an exemplary embodiment of a POE particle counting system using current limited voltage amplitude modulation type control circuitry.

FIG. 5 is a simplified schematic showing a battery charging circuit of an exemplary embodiment of a POE particle counting system.

FIG. 6 schematically shows an exemplary embodiment of a POE particle counter having rechargeable batteries.

FIG. 7 is a functional diagram showing an operation of a POE particle counting system according to an exemplary embodiment of the invention.

FIG. 8 is a highly schematic view of a POE particle counting system that implements wireless communication between selected system components, according to an exemplary embodiment of the invention.

### DETAILED DESCRIPTION OF PREFERRED EMBODIMENTS

Ethernet has been developed by adoption of standards presented by the Institute of Electrical and Electronic Engineers (IEEE) and designated as IEEE 802.3. Such technology includes specifications for communications between network devices including computers and instrumentation. Transmission lines for Ethernet are also specified by IEEE, and include twisted-pair cabling that is lower in cost than coaxial cabling as a result of a use of conventional unshielded copper wires such as those used for telephones.

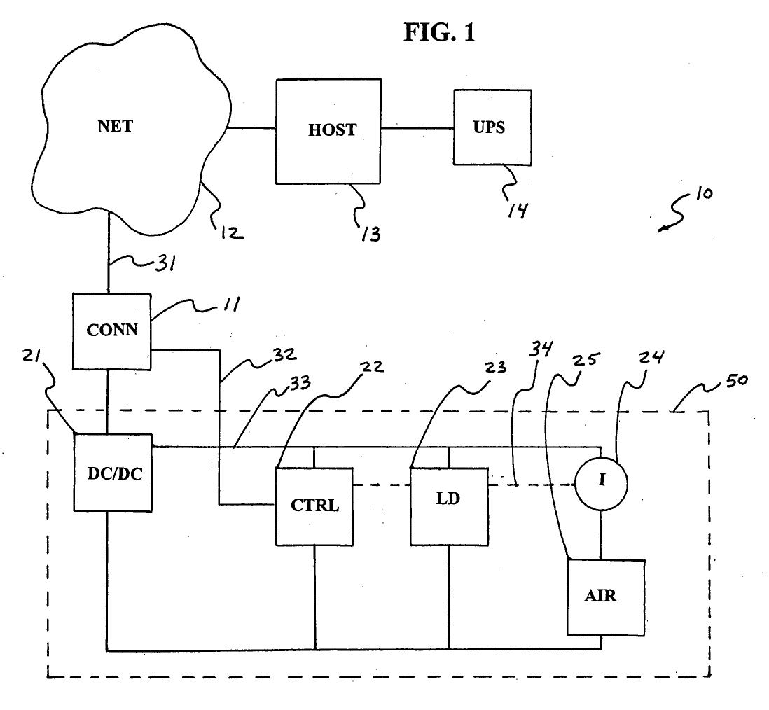

FIG. 1 schematically shows an exemplary Ethernet-powered particle counting system 10. An Ethernet subsystem 11 connects a particle counter 50 to an Ethernet type network 12 that may include a host computer 13. Host computer 13 may alternatively be located in a network that is connected indirectly to Ethernet network 12. Computer 13 preferably is connected to an uninterruptible power supply (UPS) 14 for maintaining uninterrupted electrical power to computer 13. Ethernet subsystem 11 is adapted for power over Ethernet (POE), a standard for Ethernet specified in IEEE 802.3af and having proposed additions for future use.

Ethernet subsystem 11 includes one or more connectors and/or phantom power removal circuitry for being connected to Ethernet network 12 via Ethernet cabling 31. For example, transmission line(s) 31 may be specified by IEEE 802.3 as 10BASE-T, 10BASE-F, 100BASE-T, 1000BASE-T, etc. Ethernet subsystem 11 is adapted for receipt and/or transmission of data between particle counter 50 and computer 13, and for receipt of DC power from Ethernet cable(s) 31 for supplying power to particle counter 50. The power source providing the DC power may reside in computer 13, network 12, or subsystem 11, and is described by example below. POE may be readily adapted for implementing an UPS system 14 because such an UPS may be a standard off-the-shelf (OTS) computer UPS, in the present case being used for backup power for a host computer 13 of a particle counting network 10.

Particle counter 50 has a laser and laser driver circuit 23 for producing laser illumination of a particle sampling chamber (not shown), a detector and flow control circuit 22 for detecting light scattering or extinction caused by the laser light hitting particles flowing through the sample chamber and for controlling sample air flow through the sample chamber, an air mover 25 such as a blower, and a current detector 24 for measuring electrical current being drawn by air mover 25. A laser is preferably a laser diode such as one with a 50 milliwatt output, although it is also possible to use a laser diode with a 1, 2, or 3 watt or other output. Although a conventional gas tube type laser, such as a HeNe laser may be used, such may present additional design problems due to higher power consumption. Detector and flow control circuit 22 preferably has a microprocessor for accurately processing detected data, sensing flow and current changes, and controlling operation of air mover 25.

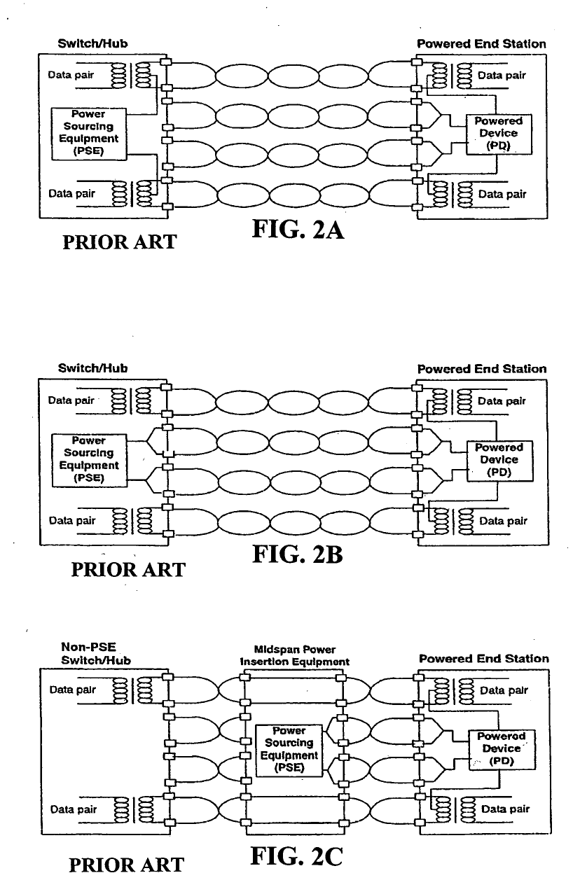

Ethernet subsystem 11 acts to separate, from Ethernet cable 31 and/or data and control lines 32, data transmissions and DC electrical power. Exemplary configurations for implementing Ethernet subsystem 11 are shown schematically in FIGS. 2A-2C. The separated-out DC power is fed to DC/DC converter 21, which converts a nominal 48 VDC to voltages required by circuitry of particle counter 50 including particle detection/flow control/system control circuitry 22, laser diode and drive circuitry 23, air mover 25, and any other circuitry of particle counter 50. For example, DC/DC converter 21 may provide 48 volts to air mover 25, 12 volts to laser diode circuit 23, 5 volts to a controller of detector/controller circuit 22, and other voltages via DC power lines 33. Although these lines 33 are shown schematically grouped together, they are separate lines that may include separate feedback loops having a current being drawn by individual components of particle counter 50. For example, a current feedback signal line 34 transfers a signal, representing the current being drawn by air mover 25, to controller 22 for regulating air flow based on the air mover current and on a sensed mass flow. Examples of such a use are discussed below. Current feedback signal line 34 may also be fed to various control circuits that adjust particle counter operations based on maintaining total power consumption within a specified limit. For example, a battery may be switched on for powering ancillary circuitry when a blower motor current exceeds a predetermined threshold for a predetermined period of time.

Mass flow sensing element 51 may be obtained from Honeywell/Microswitch. Preferably, mass flow sensing element 51 has a nominal flow of 200 cc/min. and an excess flow from the 1 CFM is directed to a shunt that bleeds off the flow to the sensor. Such a configuration may utilize a bypass containing sensing element 51 that receives only a sample of the total flow. The amount of flow directed to the bypass channel and sensing element 51 is determined by a bypass ratio that may be easily determined, for example, by calculating a ratio between the cross sectional area of the sensor 51 flow channel and the cross sectional area of the main flow channel at its point of greatest restriction. Changing the ratio and/or adjusting particular structure affecting flow may be done for changing predictability and stability of the sensor output. An alternative system for sensing the airflow through particle counter 50 may utilize a differential pressure type sensing element that measures a change in air pressure across an orifice where, for example, a pressure drop of one inch of water is proportional to a flow rate of 1 CFM. Other structures may also be used for determining air flow through a measurement portion of particle counter 50.

Detector/flow controller/microprocessor circuit 22 includes a particle sensor portion (not shown) that includes a photodetector and preamplifier positioned along the laser beam axis that provide a measure of relative intensity of illumination from the scattering of the laser light by the particles entrained in the air flowing through a sensing cavity. An example of a suitable sensing chamber is described in RE37,353, incorporated herein by reference. The present inventor has determined that it is possible to maintain a 1 CFM blower that has a low power consumption, thereby allowing the blower to maintain a 1 CFM flow rate in a 15 watt POE class. One such blower is a brushless DC blower having low friction and a centrifugal form. A blower 25 can include a centrifugal type including a regenerative centrifugal blower, a rotary vane pump, a diaphragm pump, a piston pump, a roots rotating lobe pump, a variable speed type, a cross flow type, a vortex type, an AC power vane type, as well as an axial flow fan, a vacuum connection such as a “house vacuum” system that has no resident pump, other air moving devices having motors, and other air movers including those known in the particle counting art. For example, a particle counting system 50 may include an air moving device for drawing air through the particle sensor. Such air moving device may include a motor that is directly powered via a PSE, and may be used in conjunction with a particle sensor having a low pressure drop nozzle adapted so that a total power requirement for the air moving device and the remaining components of particle counting system 50 is below the maximum power (e.g., 12.95 watts) able to be supplied by the PSE. A low pressure drop air flow system is described, for example, in U.S. Pat. No. 5,515,164, incorporated herein by reference. A high pressure drop nozzle may alternatively be used. Other structure adapted for removing turbulence, aerodynamic focusing, improving flow efficiency, etc. may be used for further reducing power consumption.

A particle counter may be connected to a network shared by other devices and computers that are not necessarily a part of the particle counting system. In such a system, the particle counter and the other networked devices may each have their own unique addresses on the network. For example, the computer may communicate with a networked particle counter via an addressed Ethernet port in order to effect a data transfer. Each Ethernet network interface card (NIC) is issued a globally unique medium access control (MAC) or physical address. When an NIC is used to connect a device to an Ethernet LAN, all machines (i.e., particle counters) in the LAN have their own unique addresses. In an installation of a particle counting system having an Ethernet data transfer, an Ethernet cable may feed the particle counter directly or via a separate Ethernet communications box. In either case, Ethernet subsystem 31 prepares and sends a datagram in a standard Ethernet frame format.

Particle counter 50 communicates with a host computer 13 via Ethernet port 11, providing information regarding particle counts above predetermined size threshold(s). The flow of information may be simplex or duplex, for example controlling particle counter 50 functions such as remotely turning blower 25 on/off, invoking a standby state, etc. An exemplary system adaptable for use with various different particle counters and protocols is disclosed in U.S. Pat. No. 6,606,582, incorporated herein by reference. Any suitable Ethernet protocol may be used for data transfer to host computer 13, including a protocol adapted for a Supervisory Control and Data Acquisition System. Such communication with networked host computer 13 may use an internet protocol suitable for viewing particle counting data and/or controlling particle counter 50 using a web browser. The communication may include a file transfer protocol (ftp) suitable for transferring stored data to a file on the network. The communication may include a mail transfer protocol suitable for transferring data via e-mail.

A system using POE includes Power Sourcing Equipment (PSE) and at least one Powered Device (PD). FIGS. 2A-2C shows three exemplary POE configurations (as illustrated in the IEEE 802.3af Standard) for using a PSE to provide power to a PD via twisted pair wires. FIG. 2A shows an exemplary POE phantom type configuration, the PSE being contained within a switch or hub and the power being supplied via the same pair of wires that carry the data, where the voltage is transferred to the PD over the signal wires. In such a configuration, AC coupling is used for the transmission of data. FIG. 2B shows an exemplary POE configuration where spare pairs of wires and connector terminals are used for connecting plus and minus terminals of the 48 volt PSE voltage to a PD, where the PSE is contained within the switch or hub. FIG. 2C shows a configuration where a power insertion device is placed between a conventional network switch or hub and the Powered End Station. In this case, data is passed through the power insertion device, and the PSE connects to the PD through the unused pair of pairs.

Ethernet interface 11, for example, may be adapted for being connected to an Ethernet network 12 via a connector (not shown) such as an RJ-45. In a phantom power application such as that shown in FIG. 2A, signal lines are passed through isolation transformers and also through a bridge rectifier to obtain a nominal 48 VDC. For other configurations such as the midspan power insertion application shown in FIG. 2C, extra conductors of Ethernet cabling 31 may be passed through forward biased diodes that prevent any power feedback to the network.

In conventional POE systems, the PSE detects whether a defined impedance is present for a PD connected to the network. The impedance detection step initiates a series of measurements of the PD by the PSE. During this series of measurements, the power requirements of the PD are communicated to the PSE. The PSE tests the resistance and capacitance of the PD load and applies power according to the classification of the PD when the impedance of the load is within corresponding specified limits. Subsequently, the PSE monitors the load and disconnects power when the current or voltage exceeds an allowable envelope. A PSE may include a mixed signal control section and a power section typically having a power switch, a protective device, and a current sensing device. The power switch can be implemented by a MOSFET, a bipolar transistor, a relay, etc. The protective device can be a fuse, an electromechanical circuit breaker or a positive temperature coefficient (PTC) device. Such a PSE is described, for example, in U.S. Publication 20040236967, incorporated herein by reference. Three IEEE power classes of 4, 7, and 15 watts have been defined for PDs, and a 30 watt class is forthcoming. Due to various losses, the actual usable amount of electrical power for a given class is less than the power rating for the class. For example, the 15 watt POE class PSE supplies only 12.95 watts to the PD.

Power may be supplied from the PSE to particle counter 50 on unused twisted pair(s) of wires available in some IEEE 802.3 compliant cabling, or a phantom circuit may be used for supplying electrical power on the same twisted pair(s) used for data transmissions. The proposed 30 watt POE will likely utilize unused twisted pairs in addition to phantom power, in order to maximize total power being supplied to a PD. A 50 LPM aerosol particle counter may be effected for the 30 watt POE class.

The present inventor has determined that conventional uses of POE have been limited to small low-power remote IP appliances, such as security card readers and cameras, and IP phone consoles, and that such uses are not suitable for powering a particle counter having a variable flow structure, such as by having a blower motor. Several conventional methods of implementing POE are contrary to operations such as those using a blower motor. For example, conventional POE disconnects a PD from electrical power under any of several circumstances, such as when a PSE latches a power in an off mode when an overcurrent occurs, even when such a fault condition is unrelated to performance of a blower motor. In such a case, there will be a need to reset the PSE to re-power the particle counter. The loss of power for a period of time can greatly affect the dynamics of flow through a sensing chamber, such as by entrapping particles, permitting contamination, disrupting flow smoothness, etc. In addition, such re-powering may affect operation of the particle counter air mover, such as by causing a high starting current. Conventional particle counters do not adequately regulate blower power in a way that allows for use in a POE system. Further, conventional particle counting systems typically use blowers and sensor chambers that are not adapted for operation at a low power consumption or within a controlled window. What is needed is a particle counter adapted for use in a POE system.

Conventional POE performs current and impedance detection in a PSE so that an excess current or out-of-envelope impedance of a load circuit may result in a disconnection of power to a PD. Such may not provide for uninterrupted continuous use. Prior to power up, a conventional PSE may detect a load resistance from the PD, rendering the PD a “valid device” having a resistance signature and enabling the PD to be powered up. The PSE may then use a classification current to determine the maximum supply current that a PD is allowed to draw. Such classification current is sensed by supplying low voltage initially to the PD via different classification resistances. After classification, the PSE raises the voltage to a nominal level greater than or equal to 42 volts, and then gradually allows an inrush current to produce a regulated PSE output. An output load fault causing a load current to exceed an over-current protection threshold will normally cause a PSE to switch the load off, and conventional PSE devices may create a latched condition requiring a reset function. Such would prevent a particle counter from operating correctly, even if a latching type device were modified by attempting to again power up the device by a soft-start in successive cycles. In addition, conventional PSEs are not adapted for use with large currents or large current variation. Further, conventional particle counters are not adapted for maintaining a power consumption at optimally low levels. Still further, in attempting to operate a particle counter while maintaining a sampling at a 1 CFM flow rate, conventional blowers such as an internal regenerative blower (pump) are not practically adaptable to meet the 12.95 watt ceiling. Conventional particle counters with an internal pump also have power requirements for continuous operation that exceed the available power for the 15 watt POE class. In addition, such conventional particle counters have a startup surge current that also exceeds the available power for 15 watt POE.

By comparison, a system according to the present invention acts to supplement the protections of standard POE by adding self-regulation of power consumption within a particle counter, where the self-regulation acts to prevent a PSE from disabling power to the particle counter. A particle counting system of the present invention also optimizes performance of an air mover so that low power consumption is maintained. For example, a radial centrifugal blower is adaptable for low power operation while achieving a 1 CFM flow rate. In another aspect, a particle counter of the invention optimizes a dynamic power consumption profile for a particle counter by reducing effects of blower motor variation and effects of PSE performance variation including those effects due to fluctuation in DC voltage being supplied over Ethernet cable(s). The POE systems allow transmission of electrical power on the same Ethernet cabling systems used for conventional Ethernet data communications.

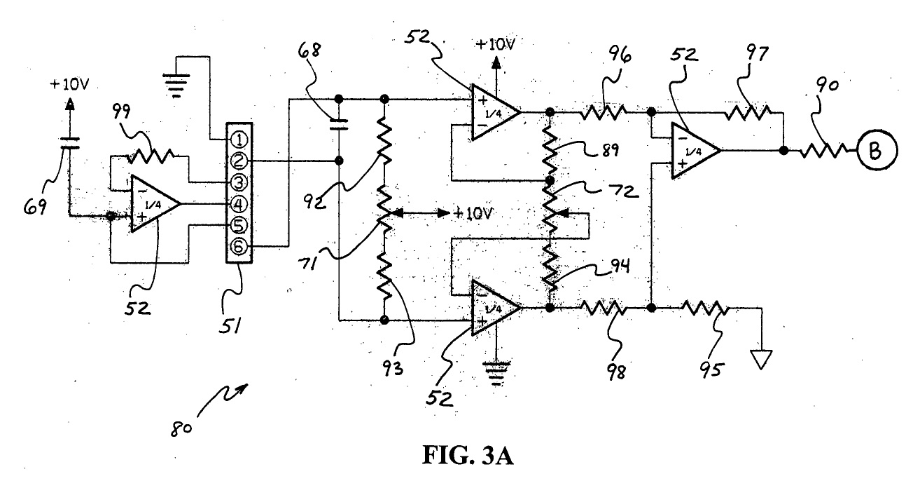

FIGS. 3A and 3B show a schematic diagram of a pump control circuit 80 that uses pulse width modulation (PWM) for controlling operation of blower 25. Pump control circuit 80 includes a mass flow sensor circuit 51, an amplifier circuit 52 having four individual amplifiers, a pulse width modulator (PWM) circuit 53, a driver transistor 54, a current sensing resistor 55, and other associated components. In this example, PWM circuit 53 may be a regulating PWM having an industry part number LT3524, available from Linear Technology. Amplifier circuit 52 may have an industry part number LT1014, also available from Linear Technology. Driver transistor may be an NPN device having an industry part number TIP-33A, and resistor 55 may have a resistance of 0.12 ohm with a 5% tolerance, preferably with a 1% tolerance. Resistor 81 is 1 Meg ohm, resistor 82 is 5.6 K ohm carbon composition, resistor 83 is 10 K, resistor 85 is 1 K, resistors 89, 94, 95, 96, 97, 98 are each 100 K, resistor 90 is 100 ohm, resistors 92, 93 are each 24.3 K, and resistor 99 is 1.82 K. Resistor 84 is preferably 10 K, and resistor 86 is either 470 ohm or 1.5 K, depending on a particular application. Variable resistors 71, 72 are 500 ohm, and variable resistor 73 is 10K. Capacitor 61 is 0.001 microfarads, capacitors 62, 69 are 0.01 microfarads, capacitors 63, 64 are 10 microfarad electrolytic, capacitor 65 is 4.7 microfarad electrolytic, and capacitor 68 is 0.1 microfarad.

Pump control circuit 80 provides an amplified voltage from mass flow sensor circuit 51 to a flow output terminal “B” via amplifiers 52. The voltage at B is then presented as a function of flow to the inverting input of PWM circuit 53 via a voltage divider set by resistors 83, 84. The non-inverting input to PWM circuit 53 is connected to a reference voltage “A” via potentiometer 73. Thus, an error voltage is presented between the inverting input and the reference on the non-inverting input of PWM circuit 53. Capacitor 62 and resistor 82 are used to set timing parameters of an oscillator section of PWM circuit 53, and capacitor 61 and resistor 81 are used for setting a duty cycle. Current sense resistor 55 is connected to current sense terminals of PWM circuit 53.

The PWM circuit 53 controls an on/off switching of transistor 54, thereby driving the pump/blower motor. The blower motor speed is varied, which varies the flow being sensed by flow sensor 51, so that a closed loop flow control is effected. Current sensing resistor 55 senses the blower current, which is input to PWM circuit 53, which switches the blower motor on/off without exceeding a predetermined current limit. A shorting jumper (not shown) may be placed across current sensing resistor 55 when a current sensing is not desired for closed loop flow control. An input is provided to PWM circuit 53 for shutting down transistor 54 by use of an external digital signal.

The closed loop PWM control includes adjusting blower motor speed based on the flow detected by flow sensor 51 which, in turn, is caused to change due to the blower motor speed, etc. By carefully damping the blower motor response to startup and to changes in sensed flow, a smooth blower operation at a target flow rate is obtained. In addition, the flow rate is affected by restriction on air being input to flow sensor 51, such as by a filter, hose, probe or other structure that changes the differential pressure of the total flow path. The closed loop operation automatically adapts to any change in such flow path by discretely changing the on/off operation of transistor 54 in response to such change, up to the point where a power level exceeds an upper predetermined limit. It is noted that many types of blower motors may experience a relatively short time to failure after any appreciable wear to components such as bearings, etc. In such a case, a defective blower motor will cause the PWM to increase power as much as possible, whereafter a continued defective flow being measured by flow sensor 51 acts to cause PWM circuit 53 to stop operation of the blower motor after a predetermined time. Such control is preferably implemented in a microprocessor algorithm of control circuitry 22 or by a system supervision program being run by a host computer 13. The external shutdown input to PWM circuit 53 may be used for disabling further operation of PWM circuit 53 when an overcurrent condition is present, or a crowbar, SCR, latch, and others may be used. An indicator light (not shown) may be illuminated for indicating when a blower motor is in need of servicing.

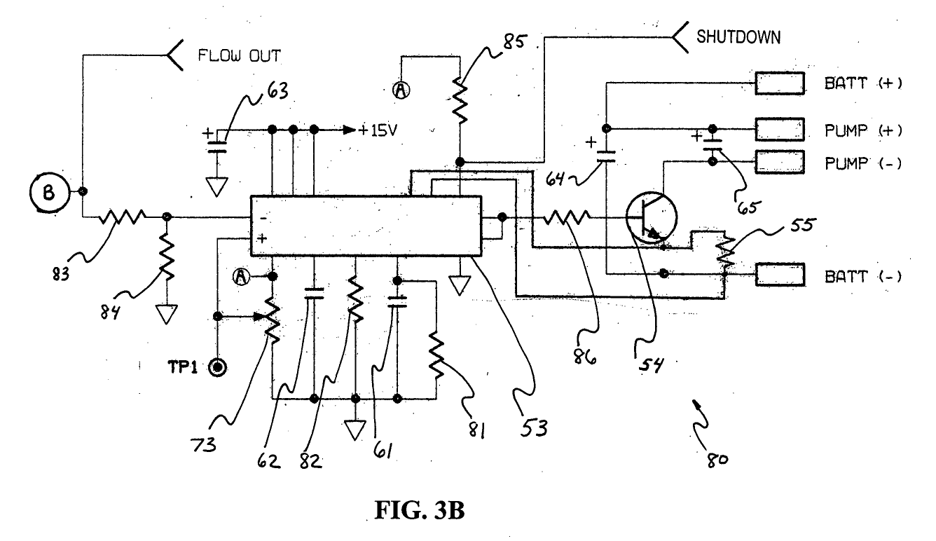

FIG. 4 in a simplified schematic shows a pump control circuit 110 using current limited voltage amplitude modulation type control circuitry. A flow sensor 51 detects a mass flow of a portion of the total flow passing through a sample chamber of a particle counter 150. Flow sensor 51 produces a signal that is fed to a multistage amplifier 111 and a stage 112 having a digital gain control 113. A flow output signal is fed to a buffering amplifier stage 115 and to an external flow output 114. Amplifier 115 feeds a normalized flow signal to the voltage feedback pin of controller 116, thereby creating an error input. While being current limited, controller 116 produces a variable voltage output that is fed to a blower motor 25 via a transistor amplifier 117 and a current-monitoring resistor 118. As the voltage driving blower motor 25 varies, the blower motor speed varies, which varies the flow sensed by flow sensor 51, thereby forming a closed loop flow control. Resistor 118, for example, may be a 0.05 ohm, 1 watt resistor that senses the blower motor current and feeds the current measurement back to a current limiting pin of controller 116, thereby providing the limit of peak current. Controller 116 may have an industry part number LT1505, available from Linear Technology.

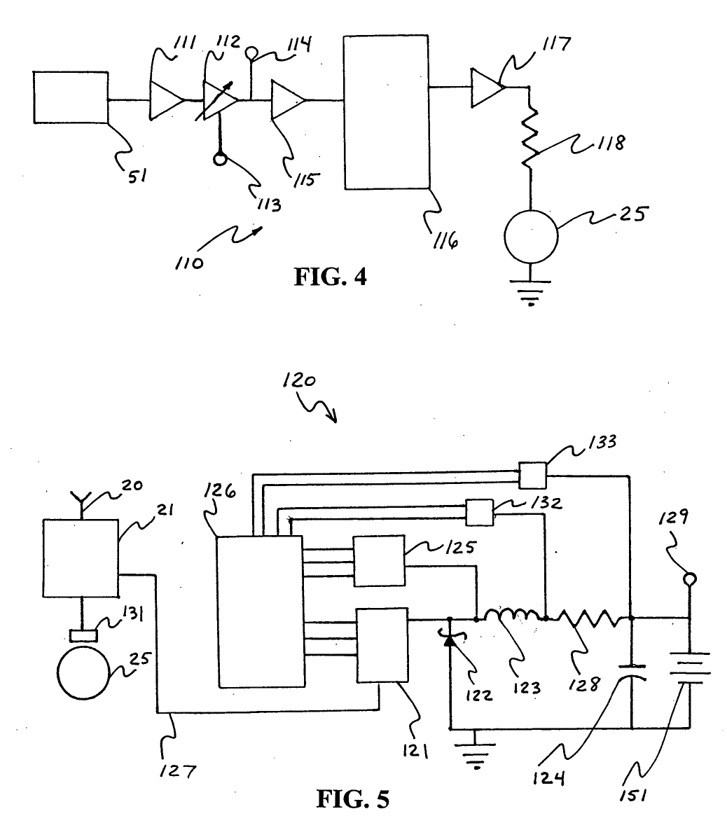

FIG. 5 in a simplified schematic shows a battery charging circuit 120. A controller 126 may be adapted for fast charging batteries 151. Controller 126 may also be an LT1505, from Linear Technology. Batteries 151 are preferably lithium-ion, nickel-metal-hydride, or nickel-cadmium type multiple cell battery assemblies. A switch output, and separate gate control outputs of controller 126 control operation of transistor switches 121 for the switching of charging current to batteries 151, where a Schottky power rectifier 122, an inductor 123, and a capacitor 124 are used for maintaining desired charging conditions. Clamping diode 122 may have an industry part number MBRS140T3 and is available from Fairchild Semiconductor, and inductor 123 in a preferred embodiment has a nominal value of ten micro Henries, but may be chosen in a range from ten to thirty micro Henries and may be obtained from Sumida and others. Power from POE is supplied to DC/DC converter 21 via system power line 20. Switching transistors 121 receive system power from DC/DC converter 21 and/or from commutator(s) 131 of motor 25 via battery voltage supply line 127, and transfer such power as a charging current to batteries 151. Transistors 121 may be those with an industry part number SI4412DY and available from Fairchild Semiconductor, Siliconix, and others. Transistors 121 are preferably biased by and bootstrapped to controller 126 via diode/capacitor networks 125. A sensing resistor 128, having a value of 0.025 ohm and a 1 watt rating, is placed in series with the charging current being supplied to batteries 151. The voltage across resistor 128 is fed to controller 126 via resistor dividers 132, 133 that further delineate a charging current by use of precision resistors, such as by a use of 200 ohm, one percent resistors. Controller 126 has internal disconnects that prevent battery drain during periods when a supply voltage is missing, and for other reasons. Controller 126 and/or batteries 129 may have disconnects to enable switching battery power on or off. Battery voltage is available via battery terminal 129.

Power consumption measurements from exemplary particle counters and sensor assemblies are now provided to illustrate various design considerations for operating a particle counter using POE. The exemplary measurements were performed by attaining certain operating conditions while providing power via a current limited laboratory power supply. Measurements were performed using a sensor assembly having a radial centrifugal blower, a low pressure drop nozzle, and an exhaust filter. Measurements were taken at flow rates of 1 CFM and 50 LPM, with and without a zero-count filter. It is noted that any suitable flow rates may be used for a particle counter of the invention, or any combination or sequence of different flow rates. The 1 CFM flow rate particle counter was maintained within the 12.95 watt limit for a 15 watt POE class, and the 50 LPM flow rate exceeded the 12.95 watt limit, but would be easily maintained for the proposed 30 watt POE class. Table I shows the performance data for the radial centrifugal blower:

TABLE I

| | VOLTAGE | CURRENT | POWER |
|---|---|---|---|
| CONDITION | (volts) | (amps) | (watts) |
| Blower begins spinning | 4.4 | 0.34 | 1.5 |
| 1 CFM w/o zero ct. filter | 5.3 | 0.63 | 3.34 |
| 1 CFM w/zero ct. filter | 7.1 | 1.18 | 8.39 |
| 50 LPM w/o zero ct. filter | 7.5 | 1.32 | 9.90 |
| 50 LPM w/zero ct. filter | 10.4 | 1.74 | 18.1 |

The remaining power consumers of particle counter 150 include a 50 mW laser diode and drive circuit at 0.75 watts, a combined assembly of a detector/flow controller/microcontroller/DC/DC converter at 2.0 watts, and an Ethernet subsystem at 1.0 watt. Where such figures are approximate, a total power consumption for apparatus other than an air mover is approximately 3.75 watts. Therefore, a total power consumption for a 1 CFM particle counter operating with POE is 12.14 watts, well within the 12.95 watt ceiling for the 15 watt POE class.

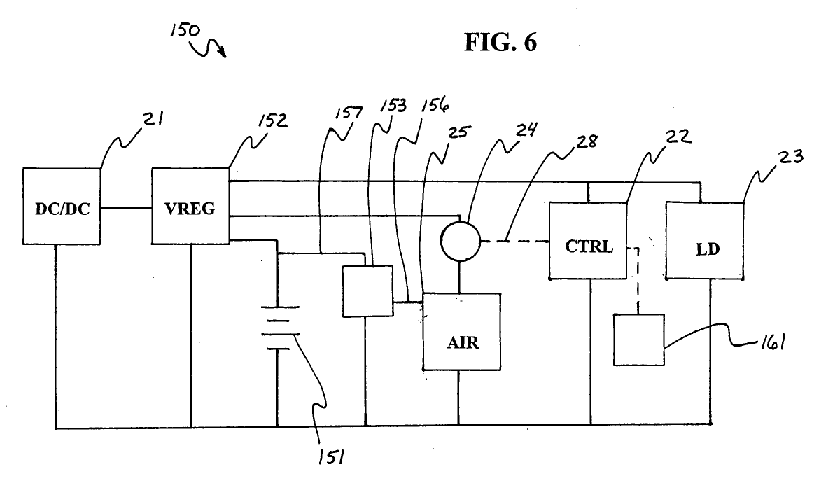

FIG. 6 schematically shows an embodiment of a particle counter 150 having rechargeable batteries 151. A voltage regulator 152 in a normal operation mode receives electrical power from the Ethernet via DC/DC converter 21 in a manner as described above for particle counter 50. Voltage regulator 152 is also connected to rechargeable batteries 151, which act as a second source of electrical power to be supplied to operate particle counter 150 in the event of a disconnection of power being supplied from a PSE via the Ethernet or similar problem, when a user desires to remove particle counter 150 from its connection to the Ethernet and, for example, carry particle counter 150 as a portable unit to sample various locations within an environment, for providing a power boost to supplement the POE power supply, and for other reasons, such as for maintaining a constant voltage in the event of occasional power spikes in a blower motor circuit. In an exemplary configuration, batteries 151 are charged by a charger 153 that receives a charging current from rotation of blower motor 25. Such charging action adds negligible mechanical resistance to rotation of blower motor 25. Protective diodes are used to prevent back emf.

During normal operation, batteries 151 are not used and retain their full charge as a result of continuous operation of charging circuit 153 that obtains a charging current via a commutator assembly and transfer line 156, and that regulates a charging being presented to batteries 151 via charging connect member 157. The current being drawn by motor 25 is monitored by current meter 24 via current sense line 28, for adaptive flow control and for regulating the battery charging to avoid drawing too much current. When particle counter 150 is used as a portable unit powered only by batteries 151, a charge indicator is preferably used for informing the user of the amount of service to be expected before recharging is required. An external battery charger adapter (not shown) may be used for providing a quick charging to batteries 151 such as after a portable particle counting usage, or batteries 151 may be provided as a removable module adapted for being quickly connected to an external battery charger.

In another exemplary embodiment, a particle counter 150 is plugged into a POE “socket” 11, which charges batteries 151 while also sampling air, whereby data is collected at a fixed location and is transmitted to a host computer 13. Particle counter 150 could then be unplugged from the POE socket and taken to other locations to collect data under battery power, storing particle counting data in an internal memory 161, for example a non-volatile RAM, a FLASH memory, or other suitable low power memory device. When the remote data accumulation has been completed and particle counter 150 has again been plugged into a POE Ethernet connection socket 11, the stored data may then be transferred to host computer 13.

In another exemplary embodiment, batteries 151 are continuously being charged by the voltage being supplied directly from DC/DC converter 21, such as during periods when motor 25 is not running. In such a case, the charge in batteries 151 may be used for boosting the overall power supplying capabilities of particle counter 150 during periods when motor 25 is running, whereby a total power available, for example in a 15 watt POE usage, is the 12.95 net watts obtained from POE plus the additional power capabilities provided by batteries 151. As a result, a total power consumption of particle counter 150 may exceed the 12.95 watt limit for a period of time without causing a PSE to go into an over-current shutdown. In one example, particle counter 150 may include a battery pack 151 capable of supplying an amount of power in excess of that provided by POE. Such a battery pack 151 accommodates a particle counter 150 having a substantially high flow rate or an inefficient pump, whereby particle counter 150 exceeds a continuous power level available from POE. In such a case, particle counter 150 is programmed to turn on intermittently and use the stored battery power to operate for a period of time determined by a dynamic power usage algorithm or for a predetermined time. As a result, particle counter 150 collects data for the time of operation and then reverts to a standby mode when the allocated time has elapsed and batteries 151 require a period of recharging.

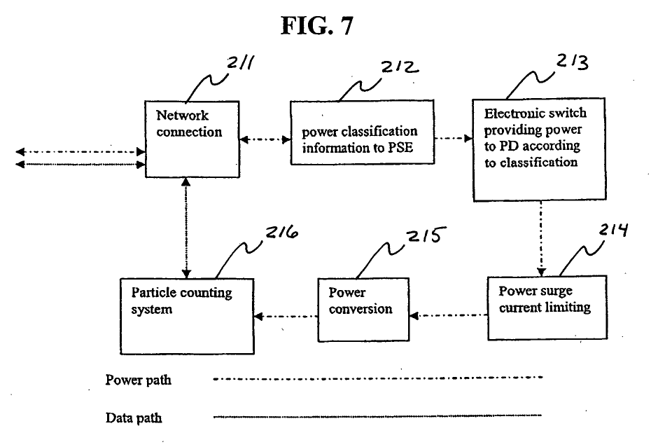

The design of a PSE allows a POE network to be transparent, so that the addition of PSEs and PDs does not degrade network data communication performance or decrease network reach. A functional diagram is provided in FIG. 7, showing an operation according to an exemplary embodiment. A POE network connection 211 separates incoming data from power, and integrates outgoing data with power. The power available from POE depends on power classification information 212 being sent and accepted by a PSE. By assuring that such power classification information 212 avoids causing a PSE to disconnect, continuous particle counting operation is effected. Such assurances may be provided by switching available power to a PD that includes a particle counter according to the existing PD power classification and by switching the available power by various control techniques. For example, a switching operation 213 may include dynamically changing a PWM, such as by modifying a duty cycle to raise and lower power consumption slightly. Switching 213 may also be controlled by received power classification information, and by various other controls. In addition, a power consumption is damped by a current surge limiting 214 that may be effected by choosing appropriate time constants and filtering for power being supplied to a blower or other major component of an air mover. For example, current surge limiting 214 may be integrated with a soft starting of a blower motor for limiting inrush current. Nominal POE voltage may be 48 volts, which is a suitable voltage for powering a blower motor, but such voltage is required to be converted to lower voltages, such as +5 or +12 volts for operating circuitry of a particle counter. Therefore, a voltage conversion operation 215 is provided. A particle counting operation 216 produces data that is transferred to the Ethernet data being transmitted, and obtains control data from the network connection 211. Particle counting operation 216 may include self-regulation of electric power consumption in addition to the operations being performed after separation of power from the Ethernet network connection.

When particle counter 50, 150 is plugged into a POE socket, a PSE senses the detection circuit when a particle counter 50, 150 is connected, and supplies power to particle counter 50, 150 via the conductors of the Ethernet cable 31. A PSE may disengage power on an Ethernet twisted pair when a particle counter is disconnected. Such disconnection may be detected as a result of the PSE continuously or periodically transmitting a load verification signal and determining that a PD meeting predetermined criteria is absent. This detection can also include a determination of impedance or device type for a PD being connected. Such a detection is disclosed in U.S. Pat. No. 6,448,899, incorporated herein by reference. However, conventional POE does not teach a POE-powered device that maintains its power consumption within specified limits for assuring continuous electrical supply. DC/DC converter 21 may include a peak power limiter circuit that assures that particle counter 50, 150 does not exceed the limits of power supplied by the PSE. This is in addition to the power regulation process being performed by the PSE, which includes the aforementioned impedance measurements and/or a standard POE power classification that uses a 20 VDC applied signal to measure a current and classify a power level of a PD, and is in addition to the other current limiting protection of particle counter 50, 150 described above. Further, DC/DC converter 21 may present a faux signal to a PSE that indicates a normal power level or normal power classification information, even when a particle counter 50, 150 is actually outside normal operating levels. In such a case, DC/DC converter 21 has current limiting or isolation circuitry that temporarily lowers or removes excess power or that supplements POE power capabilities with battery power. Such a process may be implemented, for example, to avoid a resetting of a PSE.

It is noted that in conventional POE systems, two detection schemes are specified within the IEEE standard for determining whether a PD has been removed, DC and AC disconnect. The DC disconnect process determines whether a current has fallen below a predetermined level. If so, the power to the PD is removed. The AC disconnect process applies a low frequency AC current and then measures the voltage. Under load, such voltage is low, and when a load has been disconnected the AC voltage is relatively large. When power is applied to a PD, the load is continuously or periodically monitored to ensure it is within an allowable envelope of current, voltage, etc. If not, the power is disconnected.

A particle counter 50, 150 may implement various alarm messages and/or signals for particle counting operations, air mover performance, excess power usage, etc. For example, an alarm circuit may be structured for creating an alarm when it is determined that the data includes one of a number of particle counts and a profile of sized particle counts outside a corresponding predetermined range.

A particle counting system according to the invention may have its components physically separated and/or adapted for use with a wireless communication between components. For example, POE may be used for power and data transmission between particle counters and for powering a wireless access point that communicates particle counting data (e.g., from a remote particle counter) and command messages (e.g., to a remote particle counter) by wireless communication. In such a case, components of the particle counting system may physically disconnected from the Ethernet network. A system may have several wireless components in various locations within a facility such as a pharmaceutical manufacturing area where it is impractical to run Ethernet cabling to each component.

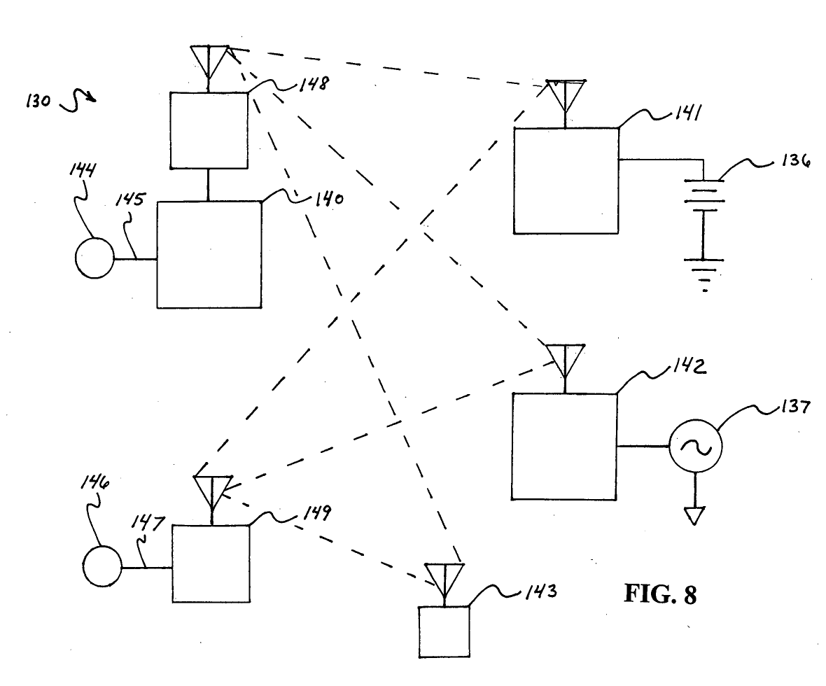

FIG. 8 is a highly schematic view of a POE particle counting system 130 that implements wireless communication between selected system components, according to an exemplary embodiment of the invention. As shown in FIG. 8, a wireless particle counting system incorporates a particle counter 140 that is powered by a PSE 144 via POE that includes an Ethernet cable 145. Particle counter 140 produces particle counting data that is fed to a host computer via Ethernet cable 145. Access point 148 receives particle counting data from remote particle counters 141, 142 via wireless communication, and feeds the received data to particle counter 140 which, in turn, sends the particle counting data from particle counters 141, 142 to the host computer, either directly or indirectly. Such an indirect communication of the remote particle counting data may include reformatting data into accumulations or by other data processing. Particle counter 141 is powered by a battery 136 and may be, for example, a portable particle counter that is carried to various locations within the facility. Particle counter 142 is powered by an AC line voltage 137, for example a hard-wired conduit connection that is impervious to cleaning fluids and the like. An independent access point 149 is powered by a PSE 146 via POE that includes an Ethernet cable 147. Access point 149 receives data and transfers such data to a host computer via Ethernet cable 147. The data being sent by access point 149 may be received from particle counters 141, 142 via wireless communication. Operational commands may be sent from particle counter 140 via access point 148 to either of particle counters 141, 142, such as for causing an on/off or standby mode. Such operational commands may also be sent from a host computer via access point 149 to either of particle counters 141, 142. A mass flow sensor 143 may be positioned to measure an air flow in a certain location, usually adjacent to or in a bypass for a particle sensing chamber. Flow sensor 143 typically has a very low power requirement and is powered by a DC voltage obtained from any convenient source, such as from an adjacent instrument or machine. Flow sensor 143 is adapted for wireless transmission of flow data to either of access points 148, 149. Other types of sensors may be used in a manner similar to that shown for mass flow sensor 143. For example, various environmental sensors may be implemented using any of POE, battery power, AC power, slave power, etc., either in a wireless or wired configuration. Such environmental sensors may be used for detecting temperature, humidity, differential pressure, and/or process related measurements and/or event detections. A method for wireless communication of particle counting information is disclosed in U.S. Pat. No. 6,346,983, incorporated herein by reference. By incorporating POE into a particle counting system, many configurations, such as one implementing wireless communication, are possible.

While the principles of the invention have been shown and described in connection with specific embodiments, it is to be understood that such embodiments are by way of example and are not limiting. Consequently, variations and modifications commensurate with the above teachings, and with the skill and knowledge of the relevant art, are within the scope of the present invention. The embodiments described herein are intended to illustrate best modes known of practicing the invention and to enable others skilled in the art to utilize the invention in such, or other embodiments and with various modifications required by the particular application(s) or use(s) of the present invention. It is intended that the appended claims be construed to include alternative embodiments to the extent permitted by the prior art.

What is claimed is:

1. A system comprising:
a particle counter having a data output;
an Ethernet cable adapted for connecting the data output of the particle counter to a monitoring station; and
a power over Ethernet (POE) type power supply structured for providing power to the particle counter via the Ethernet cable.

2. The system of claim 1 wherein the POE type power supply is adapted for being powered by the monitoring station.

3. The system of claim 1 further comprising the monitoring station.

4. The system of claim 3 further comprising an uninterruptible power supply (UPS) structured for maintaining electrical power to the monitoring station during a power outage.

5. The system of claim 1 wherein the POE type power supply comprises an endpoint type power sourcing equipment (PSE) structured to be in electrical communication with one of center taps of two Ethernet data transformers and designated conductors of the Ethernet cable.

6. The system of claim 1 wherein the POE type power supply comprises a midspan insertion type PSE.

7. The system of claim 1 further comprising a power detector structured for monitoring power usage of the particle counter.

8. The system of claim 7 wherein the power detector is structured for communicating information regarding the power usage to the PSE.

9. The system of claim 1 wherein the particle counter includes a power converter structured for adapting power obtained from the POE type power supply in order to supply electrical requirements of the particle counter.

10. The system of claim 9 wherein the power converter is structured for obtaining information regarding power consumption of the particle counter and includes a power limiter adapted for maintaining power consumption of the particle counter below a power amount being supplied by the POE type power supply.

11. The system of claim 10 wherein the power limiter comprises a peak power limiter.

12. The system of claim 10 wherein the power limiter comprises a pulse width modulation (PWM) type power regulator.

13. The system of claim 10 wherein the power limiter comprises a current limited voltage amplitude modulation type power regulator.

14. Apparatus comprising a particle counter having an air movement device adapted for being powered solely by a power over Ethernet supply.

15. Apparatus of claim 14 wherein the air movement device comprises a blower capable of moving approximately 1 CFM.

16. Apparatus of claim 14 wherein the air movement device comprises a blower capable of moving approximately 50 LPM.

17. Apparatus of claim 14 wherein the air movement device comprises a radial centrifugal type blower.

18. Apparatus of claim 14 wherein the air movement device comprises a regenerative centrifugal type blower.

19. Apparatus of claim 14 wherein the air movement device comprises a variable speed blower

20. Apparatus of claim 14 wherein the particle counter outputs particle-related measurement data, the apparatus further comprising an alarm circuit structured for creating an alarm when it is determined that the data includes one of a number of particle counts and a profile of sized particle counts outside a corresponding predetermined range.

21. Apparatus of claim 14 having a particle detection zone and a nozzle, the nozzle being adapted for drawing particles through the particle detection zone at a flow rate suitable for discretely detecting a presence of individual particles within the particle detection zone when the air movement device effects a 1 CFM total flow.

22. Apparatus of claim 14 wherein the particle counter is adapted to implement a data acquisition protocol suitable for data transfer to a Supervisory Control and Data Acquisition System.

23. Apparatus of claim 14 further comprising a power management subsystem having a power-limiting circuit structured to limit a peak power being supplied to the air movement device.

24. Apparatus of claim 23 wherein the power-limiting circuit includes a modulator adapted to change an amount of power being supplied to the air movement device based on a measurement of the peak power.

25. Apparatus of claim 24 wherein the modulator includes a pulse width modulation circuit.

26. Apparatus of claim 14 further comprising a computer for communicating with the particle counter via an Ethernet type input/output member.

27. Apparatus of claim 26 wherein the computer is adapted for controlling power consumption of the particle counter.

28. Apparatus of claim 27 wherein the controlling of power consumption includes one of an on/off operation of the low-power air movement device and a standby mode of the particle counter.

29. Apparatus of claim 26 wherein the particle counter is adapted to communicate with the computer using an Internet Protocol supporting a Web Browser.

30. Apparatus of claim 26 wherein the particle counter is adapted to communicate with the computer using a File Transfer Protocol adapted for transferring stored data to a file accessible on a network.

31. Apparatus of claim 26 wherein the particle counter is adapted to communicate with the computer using an Mail Transfer Protocol suitable for transferring data via e-mail.

32. In a system having at least one remote particle counter that provides digital data over a network and that is powered by a power supply including one of an AC source and a battery source, the improvement comprising replacing the AC source or battery source with a power over Ethernet type power supply.

33. The system of claim 32 wherein the improvement further comprises adapting an air mover of the remote detector to operate within a power range able to be supplied by the power over Ethernet supply.

34. A system comprising:
a particle counter having an air mover, a power management subsystem, and an Ethernet data output, the power management subsystem structured for monitoring power consumption of the air mover and maintaining the power consumption below a predetermined amount; and
an external electrical supply structured for powering the particle counter via an Ethernet medium using a power over Ethernet (POE) type power source.

35. The system of claim 34 wherein the air mover comprises one of a variable speed blower, a radial centrifugal blower, a regenerative centrifugal blower, a rotary vane pump, a diaphragm pump, a piston pump, a roots rotating lobe pump, and an external house vacuum system.

36. The system of claim 34 wherein the predetermined amount of power is based on a power rating of the POE power source.

37. A method comprising:
providing a particle counter having an Ethernet data output; and
providing an external electrical supply for powering the particle counter via an Ethernet medium using a power over Ethernet (POE) type power source.

38. The method of claim 37 further comprising providing an air moving device for drawing sample air through the particle counter, the air moving device adapted for being powered solely by the POE type power source.

39. The method of claim 38 further comprising providing a power regulator structured for maintaining a power consumption of the air moving device below a predetermined amount.

40. The method of claim 38 further comprising providing a control circuit structured for remotely controlling an operation of the air moving device.

41. The method of claim 38 further comprising providing the particle counter with an interface circuit structured for receiving at least one external command and, based on the external command, modifying a power consumption of and/or turning the air moving device on/off.

42. The method of claim 37 further comprising providing a communications circuit adapted for communicating with a networked computer via the Ethernet medium using a data acquisition protocol adapted for data transfer to a supervisory control and data acquisition system.

43. The method of claim 37 wherein the particle counter is adapted for communicating with a networked computer via an Internet protocol adapted for use with a web browser.

44. The method of claim 37 wherein the particle counter is adapted for communicating with a networked computer via a File Transfer Protocol (FTP) adapted for transferring stored data to a network file.

45. The method of claim 37 wherein the particle counter is adapted for communicating with a networked computer via a mail transfer protocol adapted for transferring the data in an e-mail message.

46. A method comprising:
powering a remote particle counter over an Ethernet medium via a power over Ethernet type power supply;
detecting microscopic particles with the particle counter and producing digital data based on the detecting; and
transmitting the data over the Ethernet medium.

47. A system comprising:
a power over Ethernet (POE) supply having a power supply adapted to transfer electrical power over an Ethernet cable that includes a data carrier;
a wireless access point adapted for receiving a wireless data transmission and transferring the data from the transmission via the Ethernet cable;
a wireless component structured for communicating with the wireless access point; and
a particle counter that counts particles and outputs particle counting data.

48. The system of claim 47 wherein the particle counter includes the wireless component adapted for transmitting the particle counting data to the access point.

49. The system of claim 47 wherein the particle counter receives particle data from the access point.
